(19) United States
(12) Patent Application Publication
(10) Pub. No.: US 2025/0031423 A1
(43) Pub. Date: Jan. 23, 2025

(54) METHOD FOR SYNTHESIZING NOBLE METAL-SEMICONDUCTOR HETEROSTRUCTURES AND PHOTOCATALYTIC SYSTEM FOR SIMULTANEOUSLY PHOTOCATALYTIC CONVERSION OF CARBON DIOXIDE AND MICROPLASTIC INTO CARBON MONOXIDE

(71) Applicant: City University of Hong Kong, Hong Kong (HK)

(72) Inventors: Hua ZHANG, Hong Kong (HK); Li ZHAI, Hong Kong (HK); Zijian LI, Hong Kong (HK); Hua YANG, Hong Kong (HK)

(21) Appl. No.: 18/355,417

(22) Filed: Jul. 20, 2023

(51) Int. Cl. H01L 29/267; B01J 35/00; B01J 37/04; B01J 37/08; H01L 29/04; H01L 29/06

(52) U.S. Cl. CPC H01L 29/267; B01J 35/19; B01J 35/39; B01J 37/04; B01J 37/08; H01L 29/045; H01L 29/0669

(57) ABSTRACT

A method for synthesizing noble metal-semiconductor heterostructures includes the following steps S1 to S6. Step S1: noble metal seeds are formed. Step S2: at least one metal precursors including a first metal and a first solvent are mixed in a first reactor chamber, so as to obtain a first solution comprising a first mixture. Step S3: the first solution is heated with a first heating process, so as to obtain a transparent solution. Step S4: the noble metal seeds, the transparent solution, and a second solvent are mixed, so as to obtain a second solution. Step S5: the second solution is heated with a second heating process to grow a semiconductor structure containing the first metal on the noble metal seeds, thereby forming the noble metal-semiconductor heterostructures therein. Also, a photocatalytic system including the aforesaid noble metal-semiconductor heterostructures is provided.

### FIELD OF THE INVENTION

The present invention generally relates to a method of synthesizing heterostructures and a photocatalytic system. More particularly, the present invention relates to a method of synthesizing noble metal-semiconductor heterostructures and a photocatalytic system including the aforesaid synthesized noble metal-semiconductor heterostructures.

### BACKGROUND OF THE INVENTION

Heterostructures have attracted tremendous attention due to their physicochemical properties arising from their morphologies, interfaces, and spatial arrangements of different components. The precise control over their nanoscale structures is essential to understand the structure-property correlation and enhance their performance in various applications, such as electronics, catalysis, solar energy conversion, etc. To date, the seeded/templated epitaxial growth is the most commonly used strategy to precisely tailor the hierarchical heterostructures. Epitaxial growth of a secondary material on a specific facet of the seed/template allows it to follow the crystallographic orientation of the seed/template. Combined with delicate control over the exposed facet and crystal phase of seeds/templates, this strategy has been successfully used to prepare various hierarchical heterostructures with well-defined spatial structures, interfaces, crystal phases, and programmable components.

However, the aforementioned seeded/templated epitaxial growth is mainly used to prepare heterostructures composed of components with similar lattice structures and/or chemical bonding, e.g., metal-metal, metal oxide-metal oxide, metal chalcogenide-metal chalcogenide, perovskite-perovskite, and metal-organic framework (MOF)-MOF heterostructures due to the common requirement of similar structure (normally with lattice mismatch smaller than 5%) for the epitaxial growth. Therefore, it remains a great challenge for the epitaxial growth of heterostructures made of distinctly different materials, especially for the noble metal-semiconductor heterostructures, in which two materials could have a large lattice mismatch (normally larger than 20%) and different chemical bonding. Commonly, the preparation of noble metal-semiconductor heterostructures relies on conventional non-epitaxial strategies including chemical deposition, cation-exchange-facilitated non-epitaxial growth, phase transfer, photochemical deposition, chemical extraction, sol-gel method, etc. Although the obtained non-epitaxial noble metal-semiconductor heterostructures have shown great potential in diverse fields, such as catalysis, photovoltaic devices and sensors, their wide application has been hindered due to difficulties in the precisely defined control over their structures and interfaces. Therefore, a reliable epitaxial growth method is urgently needed rationally construct hierarchical noble metal-semiconductor heterostructures with precisely controlled architectures and well-defined interfaces. In particular, there is a need for the epitaxial growth of semiconductors on noble metals with a 4H phase, or 4H/fcc phase, or 2H/fcc phase. The present invention addresses this need.

### SUMMARY OF THE INVENTION

It is an objective of the present invention to provide a method for synthesizing noble metal-semiconductor heterostructures and a photocatalytic system including the aforesaid synthesized noble metal-semiconductor heterostructures to solve the aforementioned technical problems.

In accordance with a first aspect of the present invention, a method for synthesizing noble metal-semiconductor heterostructures includes the following steps S1 to S6. Step S1: noble metal seeds are formed. Step S2: at least one metal precursors including a first metal and a first solvent are mixed in a first reactor chamber, so as to obtain a first solution comprising a first mixture. Step S3: the first solution is heated with a first heating process, so as to obtain a transparent solution. Step S4: the noble metal seeds, the transparent solution, and a second solvent are mixed, so as to obtain a second solution. Step S5: the second solution is heated with a second heating process to grow a semiconductor structure containing the first metal on the noble metal seeds, thereby forming the noble metal-semiconductor heterostructures therein.

In accordance with one embodiment of the present invention, the step S1 further includes Steps S11 to S13. The Step S11: a noble metal salt and a third solvent are mixed in a reaction chamber, so as to obtain a third solution. The step S12: the reaction chamber containing the third solution is heated with a third heating process, such that the noble metal seeds are formed in the third solution. The step S13: the noble metal seeds are collected from the reaction chamber after the third heating process.

In accordance with one embodiment of the present invention, in the step S11, the noble metal salt includes a noble metal. In the step S12, the third heating process includes a sub-step of performing an oil bath on the sealed reaction chamber with the third solvent at a constant temperature for a given time period. In the step S13, a centrifugation procedure is performed on the reaction chamber with the third solution, and then the reaction chamber is washed for a plurality of times through toluene, so that the noble metal seeds are dispersed therein.

In accordance with one embodiment of the present invention, in the step S12, the third solvent is selected from one of the following two combinations 1, 2: Combination 1: oleylamine, N-ethylcyclohexylamine, hexane and 1, 2-dichloropropane; and Combination 2: 4-tert-butylpyridine, oleylamine and heptane.

In accordance with one embodiment of the present invention, the noble metal salt comprises HAuCl₄·3H₂O.

In accordance with one embodiment of the present invention, the noble metal seeds have a 4H phase, a 4H/fcc phase, or a 2H/fcc phase.

In accordance with one embodiment of the present invention, the metal precursors comprise at least one of metal oxide comprising the first metal and metal halide comprising the first metal.

In accordance with one embodiment of the present invention, the metal precursors comprise at least one of metal oxide comprising the first metal and metal halide comprising the first metal.

In accordance with one embodiment of the present invention, the metal halide comprises chlorine (Cl).

In accordance with one embodiment of the present invention, the first metal comprises cadmium (Cd), nickel (Ni), iron (Fe), cobalt (Co), or platinum (Pt).

In accordance with one embodiment of the present invention, the metal precursor comprises metal oleate comprising the first metal.

In accordance with one embodiment of the present invention, a mixing process of the step S4 further mixes with an inorganic salt having the same element as the semiconductor structure.

In accordance with one embodiment of the present invention, the inorganic salt comprises NH₄SCN, and the same element of the inorganic salt and the semiconductor structure is sulfur(S).

In accordance with one embodiment of the present invention, the second solvent comprises oleylamine.

In accordance with one embodiment of the present invention, the second heating process comprises a sub-step of heating the second solution within a temperature range for a given time period.

In accordance with one embodiment of the present invention, the second heating process comprises a sub-step of heating the second solution with a constant temperature increasing rate for a given time period.

In accordance with one embodiment of the present invention, the method further includes a step S6: the noble metal-semiconductor heterostructures are collected.

In accordance with a second aspect of the present invention, a photocatalytic system for the photocatalytic reduction of carbon dioxide (CO₂) is provided. The photocatalytic system includes a container, a strong alkaline substance, a photocatalyst, and a photo-hole sacrificial reagent. The container, contains water. The strong alkaline substance is dissolved in water of the container. The photocatalyst includes aforesaid noble metal-semiconductor heterostructures, in which the noble metal-semiconductor heterostructures include noble metal seeds and a semiconductor structure formed thereon. The photocatalyst is dissolved in water of the container. The photo-hole sacrificial reagent is disposed in the water of the container.

In accordance with one embodiment of the present invention, the strong alkaline substance includes potassium hydroxide (KOH). The noble metal-semiconductor heterostructure includes 4H Au—CdS, 4H Au—NiS, 4H Au—Pd₄S, 4H Au—Fe₃O₄, 4H Au—NiO, 4H Au—CoO, 4H/fcc Au—CdS, or 2H/fcc Au—CdS. The photo-hole sacrificial reagent includes polyethene (PE), polyvinyl chloride (PVC), or polyethylene terephthalate (PET).

In accordance with one embodiment of the present invention, the noble metal-semiconductor heterostructures are 1D-1D heterostructures or 2D-1D heterostructures.

Based on the above, in the embodiments of the present invention, a novel wet-chemical method for precisely controlled synthesis of a library of microengineered noble metal-semiconductor heterostructures with epitaxial interfaces is provided. By performing the aforesaid steps of the synthesizing method, epitaxial growth of a library of semiconductor nanomaterials on Au nanomaterials with a 4H phase, a 4H/fcc phase, and 2H/fcc heterophase can be achieved. The synthesized noble metal-semiconductor heterostructure can have the high quantum yield of plasmon-induced charge transfer, indicating the advantage of the epitaxial noble metal-semiconductor interfaces. Also, in some cases, the synthesized noble metal-semiconductor heterostructure can be used in the photocatalytic system of the present invention for CO₂ reduction reactions. The synthesized noble metal-semiconductor heterostructure owns excellent stability. The photocatalytic system of the present invention can achieve high carbon monoxide (CO) evolution rate.

### BRIEF DESCRIPTION OF THE DRAWINGS

The patent or application file contains at least one drawing executed in color. Copies of this patent application with color drawing(s) will be provided by the Office upon request and payment of necessary fee.

Embodiments of the invention are described in more details hereinafter with reference to the drawings, in which:

FIG. 1a shows a flowchart of main steps of a method for synthesizing noble metal-semiconductor heterostructures in accordance with a first embodiment of the present invention;

FIG. 1b shows a flowchart of main sub-steps in step S1 in FIG. 1a;

FIG. 2a shows a scanning electron microscope (SEM) image of epitaxial 4H Au—CdS noble metal-semiconductor heterostructures (nanomaterials);

FIG. 2b shows a high-angle annular dark-field scanning transmission electron microscopy (HAADF-STEM) image of an one-dimensional (1D) multi-branched structure of epitaxial 4H Au—CdS noble metal-semiconductor heterostructures;

FIG. 2c shows a zoom-in high-angle annular bright-field scanning transmission electron microscope (HAABF-STEM) image of epitaxial 4H Au—CdS noble metal-semiconductor heterostructures;

FIG. 2d shows energy dispersive X-ray spectrometry (EDS) mappings of the epitaxial 4H Au—CdS noble metal-semiconductor heterostructures;

FIG. 3a shows a Cs-HAADF-STEM image of epitaxial 4H Au—CdS noble metal-semiconductor heterostructures;

FIG. 3b shows a Fast Fourier Transform (FFT) pattern of the epitaxial 4H Au—CdS noble metal-semiconductor heterostructures;

FIG. 4a shows a XRD (X-ray Diffraction) pattern of the epitaxial 4H Au—CdS noble metal-semiconductor heterostructures;

FIG. 4b shows a high-resolution XPS (X-ray photoelectron spectroscopy) spectrum of the epitaxial 4H Au—CdS noble metal-semiconductor heterostructures;

FIG. 5a and FIG. 5b show SEM images of an epitaxial 2H/fcc Au—CdS noble metal-semiconductor heterostructures (nanomaterials) at different magnifications;

FIG. 6a shows a ABF-STEM image of epitaxial 2H/fcc Au—CdS noble metal-semiconductor heterostructures;

FIG. 6b shows EDS mappings of the epitaxial 2H/fcc Au—CdS noble metal-semiconductor heterostructures;

FIG. 7a shows a Cs-HAADF-STEM image of epitaxial 2H/fcc Au—CdS noble metal-semiconductor heterostructures;

FIG. 7b shows a FFT pattern of the epitaxial 2H/fcc Au—CdS noble metal-semiconductor heterostructures;

FIG. 8 shows a selected area electron diffraction (SAED) pattern of the epitaxial 2H/fcc Au—CdS metal-semiconductor heterostructures;

FIG. 9a shows a transmission electron microscope (TEM) image of 4H Au—Ni₂S₃ noble metal-semiconductor heterostructures;

FIG. 9b shows a HRTEM image of epitaxial 4H Au—Ni₂S₃ noble metal-semiconductor heterostructure at different magnifications;

FIG. 10a shows a Cs-HAADF-STEM image of the epitaxial 4H Au—Ni₂S₃ noble metal-semiconductor heterostructures;

FIG. 10b shows EDS mappings of the epitaxial 4H Au—Ni₂S₃ noble metal-semiconductor heterostructures;

FIG. 11a shows a Cs-HAADF-STEM image of epitaxial 4H Au—Ni₂S₃ noble metal-semiconductor heterostructures;

FIG. 11b shows a FFT pattern of epitaxial 4H Au—Ni₂S₃ noble metal-semiconductor heterostructures;

FIG. 12 shows EDS mappings of the epitaxial 4H Au—Pd₄S noble metal-semiconductor heterostructures;

FIG. 13a shows a Cs-HAADF-STEM image of epitaxial 4H Au—Pd₄S metal-semiconductor heterostructures;

FIG. 13b shows a FFT pattern of the epitaxial 4H Au—Pd₄S metal-semiconductor heterostructures;

FIG. 14a shows a TEM image of epitaxial 4H Au—Co₃O₄ metal-semiconductor heterostructures;

FIG. 14b and FIG. 14c show high resolution TEM (HRTEM) images of the epitaxial 4H Au—Co₃O₄ metal-semiconductor heterostructures;

FIG. 14d shows a FFT pattern of the epitaxial 4H Au—Co₃O₄ metal-semiconductor heterostructures;

FIG. 15 shows a EDS line scan result of the epitaxial 4H Au—Co₃O₄ metal-semiconductor heterostructures;

FIG. 16 shows a Raman spectrum of the epitaxial 4H Au—Co₃O₄ metal-semiconductor heterostructures;

FIG. 17a shows a high-resolution XPS spectrum of Au 4f of epitaxial 4H Au—Co₃O₄ metal-semiconductor heterostructures;

FIG. 17b shows a high-resolution XPS spectrum of Co 2p of epitaxial 4H Au—Co₃O₄ metal-semiconductor heterostructures;

FIG. 17c shows a high-resolution XPS spectrum of O 1s of epitaxial 4H Au—Co₃O₄ metal-semiconductor heterostructures;

FIG. 18 shows a XRD spectrum of the epitaxial 4H Au—Co₃O₄ metal-semiconductor heterostructures;

FIG. 19a shows a TEM image of the epitaxial 4H Au—NiO metal-semiconductor heterostructures;

FIG. 19b shows a HRTEM image of the epitaxial 4H Au—NiO metal-semiconductor heterostructures;

FIG. 19c shows a FFT pattern of the epitaxial 4H Au—NiO metal-semiconductor heterostructures;

FIG. 20a shows a TEM image of the epitaxial 4H Au—Fe₃O₄ metal-semiconductor heterostructures;

FIG. 20b shows a HRTEM image of the epitaxial 4H Au—Fe₃O₄ metal-semiconductor heterostructures;

FIG. 20c shows a FFT pattern of the epitaxial 4H Au—Fe₃O₄ metal-semiconductor heterostructures;

FIG. 21a shows a Mid-IR femtosecond transient absorption spectrum of Cd₃P₂;

FIG. 21b shows a Mid-IR femtosecond transient absorption spectrum of CdS noble metal-semiconductor heterostructures;

FIG. 21c shows a Mid-IR femtosecond transient absorption spectrum of 4H Au—CdS noble metal-semiconductor heterostructures;

FIG. 22 shows a schematic illustration of synchronously photocatalytic CO₂ reduction and microplastic reforming using epitaxial 4H Au—CdS noble metal-semiconductor heterostructures;

FIG. 23 shows gas chromatography (GC) spectra of the gas products in the synchronously photocatalytic CO₂ reduction and microplastic reforming reactions using epitaxial 4H Au—CdS noble metal-semiconductor heterostructures;

FIG. 24a shows a GC spectrum of the products in the photocatalytic CO₂ reduction using epitaxial 4H Au—CdS noble metal-semiconductor heterostructures mixed with PE plastic;

FIG. 24b shows a GC spectrum of the products in the photocatalytic CO₂ reduction using blank epitaxial 4H Au—CdS noble metal-semiconductor heterostructures;

FIG. 24c shows a GC spectrum of the Ci products in the photocatalytic CO₂ reduction using CdS nanorods;

FIG. 25a shows CO evolution rate in the synchronously photocatalytic CO₂ reduction and microplastic reforming reactions using different plastics and photocatalysts;

FIG. 25b shows a stability test of epitaxial 4H Au—CdS noble metal-semiconductor heterostructures in the synchronously photocatalytic CO₂ reduction and microplastic reforming reactions;

FIG. 26 shows nuclear magnetic resonance (NMR) spectra of the liquid products in the synchronously photocatalytic CO₂ reduction and PE microplastic reforming reactions using epitaxial 4H Au—CdS noble metal-semiconductor heterostructures;

FIG. 27 shows TEM images of the epitaxial 4H Au—CdS noble metal-semiconductor heterostructures after the synchronously photocatalytic CO₂ reduction and plastic reforming reactions;

FIG. 28 shows TEM images of the epitaxial 4H Au—CdS noble metal-semiconductor heterostructures after the synchronously photocatalytic CO₂ reduction and plastic reforming reactions;

FIG. 29 shows NMR spectra of the liquid products in the synchronously photocatalytic CO₂ reduction and PVC microplastic reforming reactions using epitaxial 4H Au—CdS 1D-1D noble metal-semiconductor heterostructures; and

FIG. 30 shows NMR spectra of the liquid products in the synchronously photocatalytic CO₂ reduction and PET microplastic reforming reactions using epitaxial 4H Au—CdS 1D-1D noble metal-semiconductor heterostructures.

### DETAILED DESCRIPTION

In the following description, methods for synthesizing a noble metal-semiconductor heterostructure, a photocatalytic system and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

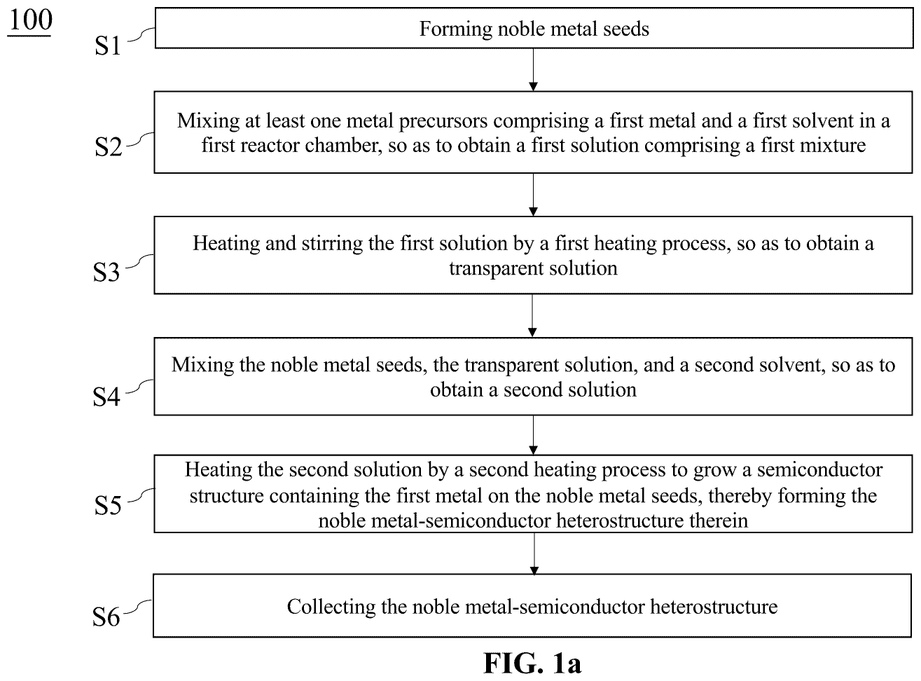

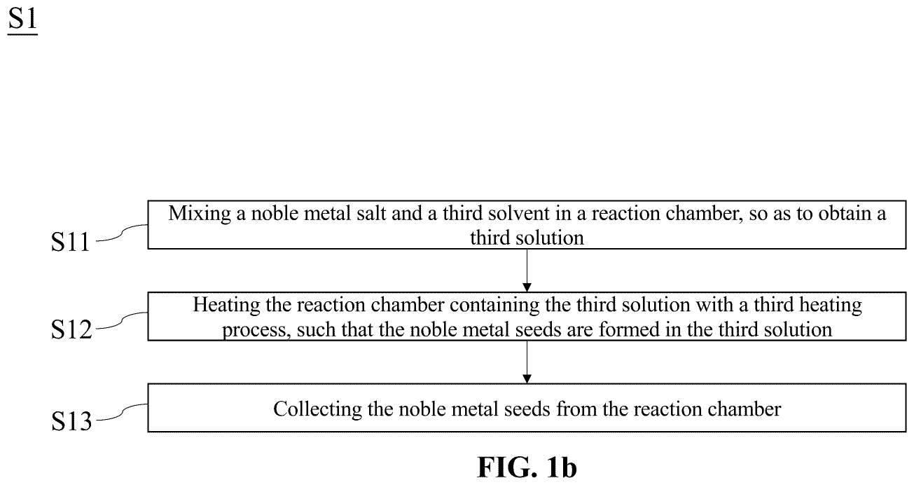

FIG. 1a shows a flowchart of main steps S1 to S6 of a method 100 for synthesizing a noble metal-semiconductor heterostructure in accordance with a first embodiment of the present invention. FIG. 1b shows a flowchart of main sub-steps S11 to S13 in step S1 in FIG. 1a.

Referring to FIG. 1a, the provided method 100 is a wet-chemical method to synthesize a noble metal-semiconductor heterostructure. In step S1, noble metal seeds with phases selected from 4H phase, or 4H/fcc phase, or 2H/fcc phase. In the embodiments of the present invention, a material of the noble metal seed is noble metal. The noble metal can be, for example, gold (Au), and the present invention is not limited thereto. On the other hand, in the embodiments of the present invention, the formed or synthesized noble metal-semiconductor heterostructure can have 4H phase, 4H/fcc (face center cubic, fcc) phase or 2H/fcc phase. Referring to FIG. 1b, The step S1 of forming noble metal seeds further includes a plurality of main sub-steps S11 to S13. Depending on the different phases, the detailed manufacturing processes of forming noble metal seeds with different phases slightly vary from each other, and they will be described in detail in the following paragraphs.

Synthesis Process of Noble Metal Seeds with 4H Phase, 4H/Fcc Phase or 2H/Fcc Phase

### Synthesis Process of 4H Phase Au Seed

Referring to FIG. 1b, in step S11, a noble metal salt and a solvent are mixed in a reaction chamber, so as to obtain a solution. In detail, in the embodiment, the noble metal salt can include, for example, noble metal, in which the noble metal can be, for example, gold (Au). Specifically, 100 mg of HAuCl₄·3H₂O is used as the noble metal salt, and components of the solvent in the step S11 includes, for example, 4 ml of 20 ml of oleylamine (98%), 4 ml of n-ethylcyclohexylamine, 184 ml of hexane, and 4 ml of 1,2-dichloropropane. It should be noted that weight and types of the noble metal salt and volumes and types of components of the solvent in step S11 can be appropriately changed according to the requirements of person having ordinary skill in the art. The reaction chamber can be, for example, 500 mL glass vial, but the present invention is not limited thereto.

Before proceeding to the next step, in order to prevent the negative impacts causing by external air, the opening of the reaction chamber can be optional sealed using a scaling member, such as polytetrafluoroethylene (PTFE) tape and parafilm, but the present invention is not limited thereto.

Referring to FIG. 1b, in step S12, the reaction chamber containing the aforesaid solution in step S11 is heated with a heating process, such that the noble metal seeds are formed in the aforesaid solution. The aforesaid heating process in the step S12 includes a sub-step of performing an oil bath on the sealed reaction chamber with the solvent in step S11 at a constant temperature for a given time period. To be more specific, the reaction chamber can be heated in an oil bath at a temperature of 58° C. for a duration of 48 hours.

Referring to FIG. 1b, in step S13, the noble metal seeds are collected from the reaction chamber after the aforesaid heating process in step S12. The collecting process can be achieved by performing a centrifugation procedure on the reaction chamber containing the aforesaid solution, for example, centrifugation at 4000 rpm for 3 minutes. Subsequently, the reaction chamber is washed a plurality of times (e.g., three times) using toluene to disperse the noble metal seeds within it. As a result, the 4H Phase Au seeds can be formed after completing steps S11 to S13. Thus, 4H Phase Au seeds can be formed after the steps S11 to S13.

### Synthesis Process of 4H/Fcc Phase Au Seed

In a synthesizing process of 4H/fcc phase Au seeds, it is generally similar to a synthesizing method of 4H Phase Au seeds, and the main difference lies in that: the temperature of the heating process in S12 step is different, which is, for example, 80° C. The detailed synthesis process of 4H/fcc phase Au seeds is described in this paragraph. 100 mg of HAuCl₄·3H₂O, 20 mL of oleylamine (98%), 4 ml of N-ethylcyclohexylamine, 184 mL of hexane and 4 ml of 1,2-dichloropropane are thoroughly mixed in a 500 mL glass vial. The vial is then sealed with PTFE tape and parafilm before being heated for 48 h in an oil bath pre-set at 80° C. The product (i.e., 4H/fcc phase Au seeds) is collected by centrifugation at 4000 rpm for 3 min, washed with toluene three times, and then redispersed in 10 mL of toluene.

### Synthesis Process of 2H/Fcc Phase Au Seed

In a synthesizing process of 2H/fcc phase Au seeds, it is generally similar to a synthesizing method of 4H/fcc phase Au seed, and the main difference lies in that: components of the solvent used in the step S11 are different, which are, for example, 30 mL of 4-tert-butylpyridine, 40 mL of oleylamine (98%) and 50 mL of heptane. The detailed synthesis process of 2H/fcc phase Au seeds is described in this paragraph. 100 mg of HAuCl₄·3H₂O, 30 mL of 4-tert-butylpyridine, 40 mL of oleylamine (98%) and 50 mL of heptane are thoroughly mixed in a 500 mL glass vial. The vial is then sealed with PTFE tape and parafilm before being heated for 4 h in an oil bath pre-set at 80° C. The product (e.g., 2H/fcc Phase Au seeds) is collected by centrifugation at 5000 rpm for 3 min, washed with toluene three times, and then redispersed in 10 mL of toluene.

Next, other steps S2 to S6 of synthesizing method 100 will be described in the following paragraphs. Since the synthesis processes of different noble metal-semiconductor heterostructures are slightly different from each other, firstly, the detailed synthesis process of a single noble metal-semiconductor heterostructure (e.g., 4H Au—CdS) will be described below in conjunction with the steps S2 to S6.

### Synthesis Process of Noble Metal-Semiconductor Heterostructure

### Synthesis Process of Noble Metal-Semiconductor Heterostructure (4H Au—CdS)

Referring back to FIG. 1a, in step S2, at least one metal precursors including a metal and a solvent are mixed in a reactor chamber, so as to obtain a solution including a mixture. In detail, there are two types of metal precursors used in step S2, namely metal oxide and metal halide. The metal halide can include, for example, chlorine (Cl). Metal in the metal precursors serves as metal elements of prepare-to-be formed semiconductors (e.g., CdS). The used metal precursors can be, for example, 1 to 10 mg of CdO (metal oxide) and 1 to 5 mg of CdCl₂ (metal halide), and both of them include metal, cadmium (Cd). Components of the solvent in step S2 includes, for example, 1 to 5 mL of oleic acid, and 5 to 20 mL of 1-octadecene. It should be noted that weight and types of the metal oxide and metal halide, and types of components of the solvent in step S2 can be appropriately changed according to the requirements of person having ordinary skill in the art. The reaction chamber can be, for example, 50 mL three-neck flask, but the present invention is not limited thereto.

Before proceeding to the next step, it is optional to perform a step of pre-heating and pre-stirring process, and the process can ensure uniform heating of the solution in step S2 and facilitates complete chemical reaction of its components. In detail, the solution in 50 mL three-neck flask is degassed at 80 to 120° C. for 5 to 30 mins under vigorous magnetic stirring at 750 r.p.m.

In step S3, the solution in step S2 is heated and stirred with a heating process, so as to obtain a transparent solution. Specifically, the solution in step S2 is heated to 250° C. to 280° C. under N₂ atmosphere, and then the solution becomes transparent. Then, the transparent solution is cooled to 190° C. to 260° C.

In step S4, the noble metal seeds (e.g., the product collected from step S13), the transparent solution, and a solvent are mixed, so as to obtain a solution. In detail, a mixing process of the step S4 further mixes with an inorganic salt, for example, NH₄SCN. The inorganic salt NH₄SCN has the same element (e.g., sulfur) as prepare-to-be formed semiconductor structure (e.g., CdS). The solvent used in step S4 can be, for example, oleylamine. To be more specific, a mixture of 1 to 6 mg of 4H Au seeds, the transparent solution, 3 to 12 mg of NH₄SCN, and 1 to 2 mL of oleylamine are mixed in the flask.

In step S5, the solution (obtained from step S3) is heated with a heating process to grow a semiconductor structure (e.g., CdS) containing the metal (in the metal precursor, e.g., Cd) on the noble metal seeds (e.g., 4H Au seed), thereby forming the noble metal-semiconductor heterostructure (e.g., 4H Au—CdS) therein. The heating process in step S5 includes a sub-step of heating the solution within a temperature range for a given time period. In detail, the solution is heated within a temperature range 190 to 260° C. for 2 to 6 min by a heating element (e.g., a heating mantle). After step S5, the heating element is removed, such that the chemical reaction of synthesizing noble metal-semiconductor heterostructure is stopped.

In step S6, the noble metal-semiconductor heterostructure is collected. To be more specific, after the solution in step S5 is cooled down to 50 to 100° C. by removing the heating element, 5 to 10 mL of toluene is injected into the reaction flask. Then, 5 to 10 mL of ethanol is added to the solution, and the product (i.e., noble metal-semiconductor heterostructure) can be collected by performing a centrifugation procedure on the reaction flask containing the solution in step S5, for example, centrifugation at 8000 rpm for 3 minutes. The obtained precipitate can be washed with the mixture of toluene and ethanol (volume ratio: 1/1) and then dispersed into 10 mL of toluene. Thus, the synthesizing method for noble metal-semiconductor heterostructure of the present invention has been completed.

### Synthesis Process of Noble Metal-Semiconductor Heterostructure (2H/Fcc Au—CdS)

In a synthesizing process of 2H/fcc Au—CdS, it is generally similar to a synthesizing method of 4H Au—CdS, and the main difference lies in that: the used noble metal seeds (Au seed) in step S4 have a 2H/fcc phase.

The detailed synthesis process of the noble metal-semiconductor heterostructure (2H/fcc Au—CdS) is described in this paragraph. 1 to 10 mg of CdO, 1 to 5 mg of CdCl₂, 1 to 5 mL of oleic acid, 5 to 20 mL of 1-octadecene are added into a 50 mL three-neck flask and are degassed at 80 to 120° C. for 5 to 30 min under vigorous magnetic stirring at 750 r.p.m. After it is heated to 250 to 280° C. under N₂ atmosphere, the solution becomes transparent. The solution is cooled to 190 to 260° C., and a mixture of 1 to 6 mg of 2H/fcc Au seeds, 3 to 12 mg of NH₄SCN, 1 to 2 mL of oleylamine is injected into the flask, and the temperature of the flask is kept at 190 to 260° C. for 2 to 6 mins. Then, the reaction is stopped by removing the heating mantle. After the solution is cooled down to 50 to 100° C., 5 to 10 mL of toluene is injected into the reaction flask. Then, 5 to 10 mL of ethanol is added to the solution, and the product (i.e., 2H/fcc Au—CdS) is collected by centrifuge at 8,000 r.p.m. for 3 mins. The obtained precipitate is washed with the mixture of toluene and ethanol (volume ratio: 1/1) and then dispersed into 10 mL of toluene.

Synthesis Process of Noble Metal-Semiconductor Heterostructure (4H Au—Ni₂S₃)

In a synthesizing process of 4H Au—Ni₂S₃, it is generally similar to a synthesizing method of 4H Au—CdS, and the main differences lie in that: 1). The used metal precursor in step S2 only includes one type, for example, metal halide (e.g., NiCl₂). 2). The process temperature in some steps is slightly different.

The detailed synthesis process of 4H Au—Ni₂S₃ is described in this paragraph. 1 to 10 mg of NiCl₂, 1 to 5 mL of oleylamine, 5 to 20 mL of 1-octadecene are added into a 50 mL three-neck flask and degassed at 80 to 120° C. for 5 to 30 min under vigorous magnetic stirring at 750 r.p.m. After it is heated to 160 to 180° C. under N₂ atmosphere, the solution becomes transparent. A mixture of 1 to 6 mg of 4H Au seeds, 3 to 12 mg of NH₄SCN, 1 to 2 mL of oleylamine is injected into the flask, and the temperature of the flask is kept at 160 to 180° C. for 2 to 6 mins. Then, the reaction is stopped by removing the heating mantle. After the solution is cooled down to 50 to 100° C., 5 to 10 mL of toluene is injected into the reaction flask. Then, 5 to 10 mL of ethanol is added to the solution, and the product (e.g., 4H Au—Ni₂S₃) is collected by centrifuge at 8,000 r.p.m. for 3 mins. The obtained precipitate is washed with the mixture of toluene and ethanol (volume ratio: 1/1), and then dispersed into 10 mL of toluene.

### Synthesis Process of Noble Metal-Semiconductor Heterostructure (4H Au—Pd₄S)

In a synthesizing process of 4H Au—Pd₄S, it is generally similar to a synthesizing method of 4H Au—CdS, and the main differences lie in that: 1). The used metal precursor in step S2 only includes one type, for example, metal halide (e.g., PdCl₂). 2). The process temperature in some steps is slightly different from that of the 4H Au—CdS.

The detailed synthesis process of 4H Au—Pd₄S is described in this paragraph. 1 to 10 mg of PdCl₂, 1 to 5 mL of oleylamine, 5 to 20 mL of 1-octadecene are added into a 50 mL three-neck flask and degassed at 80 to 120° C. for 5 to 30 mins under vigorous magnetic stirring at 750 r.p.m. After it is heated to 160 to 180° C. under N₂ atmosphere, the solution becomes transparent. A mixture of 1 to 6 mg of 4H Au seeds, 3 to 12 mg of NH₄SCN, 1 to 2 mL of oleylamine is injected into the flask, and the temperature of the flask is kept at 160 to 180° C. for 2 to 6 mins. Then the reaction is stopped by removing the heating mantle. After the solution is cooled down to 50 to 100° C., 5 to 10 mL of toluene is injected into the reaction flask. Then, 5 to 10 mL of ethanol is added to the solution, and the product (e.g., 4H Au—Pd₄S) is collected by centrifuge at 8,000 r.p.m. for 3 mins. The obtained precipitate is washed with the mixture of toluene and ethanol (volume ratio: 1/1) and then dispersed into 10 mL of toluene.

Synthesis Process of Noble Metal-Semiconductor Heterostructure (4H Au—Fe₃O₄)

In a synthesizing process of 4H Au—Fe₃O₄, it is generally similar to a synthesizing method of 4H Au—CdS, and the main differences lie in that: 1). The used metal precursor in step S2 includes metal oleate, such as iron oleate. 2). The volumes of components of used solvent in step S2 are different from that of 4H Au—CdS. 3.) The weight of used noble metal seeds is different from that of the 4H Au—CdS. 4). The process temperatures in some steps of the synthesizing process of 4H Au—Fe₃O₄ are different from that of the 4H Au—CdS. 5.) In step S4, the previously mentioned inorganic salt NH₄SCN is not used. 6.) The heating process of step S5 includes a sub-step of heating the solution with a constant temperature increasing rate for a given time period.

The detailed synthesis process of 4H Au—Fe₃O₄ is described in this paragraph. 100 to 200 mg of iron oleate, 0.1 to 0.5 ml of oleic acid, 5 to 20 mL of 1-octadecene, and 100 to 500 mg of octadecylamine are added into a 50 mL three-neck flask and degassed at 80 to 120° C. under vigorous magnetic stirring at 750 r.p.m. After degassing for 5 to 30 mins, all of the solids are dissolved, the reaction flask is heated to 150 to 200° C., and a mixture of 1 to 10 mg 4H Au seed and 0.5 to 1 ml oleylamine is quickly injected into the flask. After the injection, the temperature is increased to 250 to 300° C. with an increasing rate of 5° C./min and kept for 1 to 2 hours. Finally, the reaction is stopped by removing the heating mantle. When the solution is cooled down to 100 to 120° C., 3 to 5 mL of toluene and 3 to 5 mL of ethanol (volume ratio: 1/1) mixture solution is injected into the reaction flask. The final product (e.g., 4H Au—Fe₃O₄) is collected by centrifuge at 7,000 r.p.m. for 5 min. The obtained precipitate is washed with the mixture of toluene and ethanol (volume ratio: 1/1) for 3 to 5 times and then dispersed into 10 mL of toluene.

The synthesis process of 4H Au—Co₃O₄ and 4H Au—NiO is similar to that of the 4H Au—Fe₃O₄, the main difference lies in that: the used metal oleate is changed into cobalt oleate or nickel oleate.

It should be noted that the formed 4H Au—CdS, 4H Au—NiS, 4H Au—Pd₄S, 4H Au—Fe₃O₄, 4H Au—NiO, 4H Au—CoO and 4H/fcc Au—CdS are 1D-1D noble metal-semiconductor heterostructures, and formed 2H/fcc Au—CdS is a 2D-1D noble metal-semiconductor heterostructure.

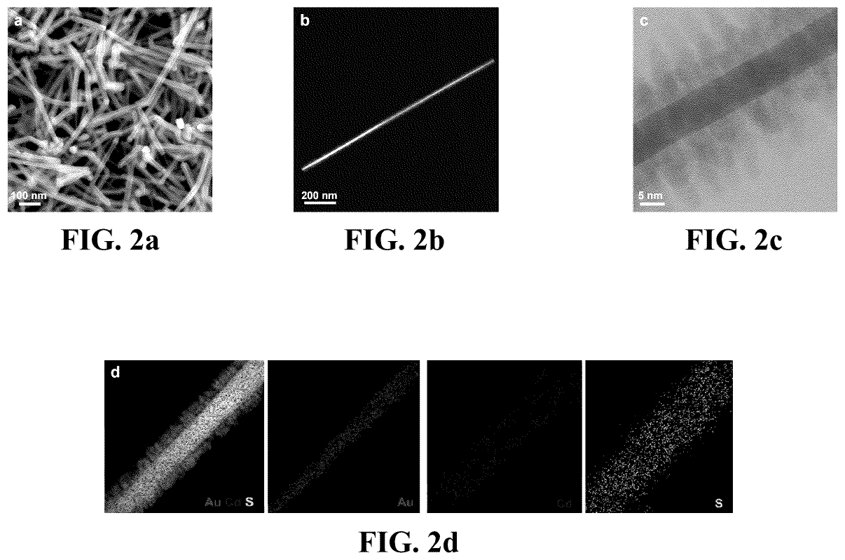

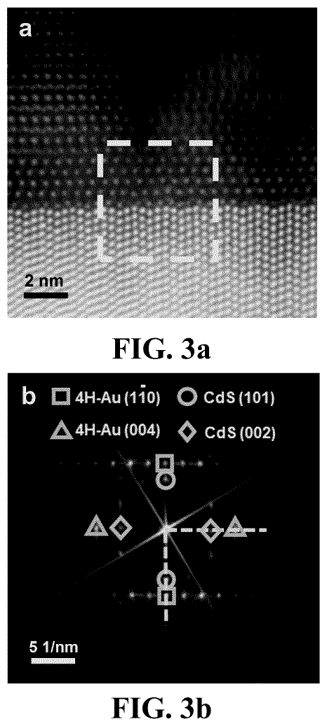

Referring to FIGS. 2a to 2d, the formed 4H Au—CdS metal-semiconductor heterostructure by aforesaid synthesizing method is characterized by high resolution transmission electron microscope (HRTEM), Cs high angle annular dark field-scanning transmission electron microscopy (Cs-HAADF-STEM), X-ray photoelectron spectroscopy (XPS) and SEM. FIGS. 2a and 2b show the 1D multi-branched structure of epitaxial 4H Au—CdS metal-semiconductor heterostructure (nano-scaled materials). The length of 4H Au seeds is about 1000 to 3000 nm and the length of CdS nanorods is about 20 to 25 nm. FIG. 2c shows that the CdS nanorods vertically grow on 4H Au seeds, and the structure of the 4H Au seeds can be, for example, nanowires. FIG. 2d shows that Cd and S elements constructed homogeneous branches on the 4H Au nanowires. FIG. 3a shows the abrupt interface between 4H Au seeds and CdS. FIG. 3b shows the aligned spots in the Fast Fourier Transform (FFT) pattern and demonstrates that the CdS nanomaterials are epitaxially grown on 4H Au seeds with an epitaxial relationship of 4H Au (110)∥CdS (101) and 4H Au (004)∥CdS (002).

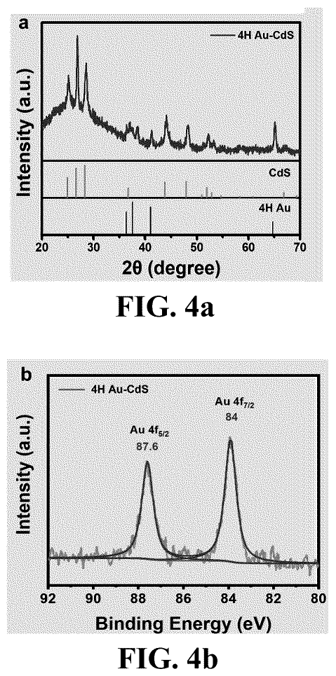

Referring to FIG. 4a, in the XRD pattern of epitaxial 4H Au—CdS metal-semiconductor heterostructure, the peaks located at 24.9°, 26.5°, 28.2°, 36.6°, 43.7°, 47.8° and 51.9° are well matched with the (100), (002), (101), (102), (110), (103) and (112) planes of wurtzite CdS, respectively. It should be noted that the peaks located at 36.2° and 42.1° can be observed, which are the characteristic peaks of 4H Au seeds, and this demonstrates that the 4H phase of Au is maintained after the growth of CdS. Referring to FIG. 3b, the high-resolution XPS spectrum of Pd 3d revealed that Pd is not sulfurized and maintained a metallic state after the growth of CdS as the peaks located at 87.6 and 84.0 eV can be ascribed to Au 4f_{5/2} and Au 4f_{7/2} of zerovalent Au, respectively.

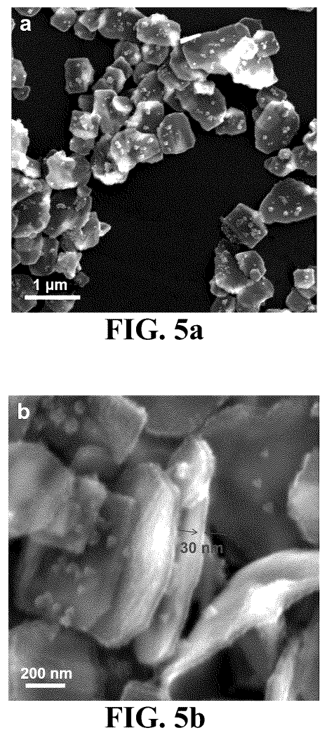

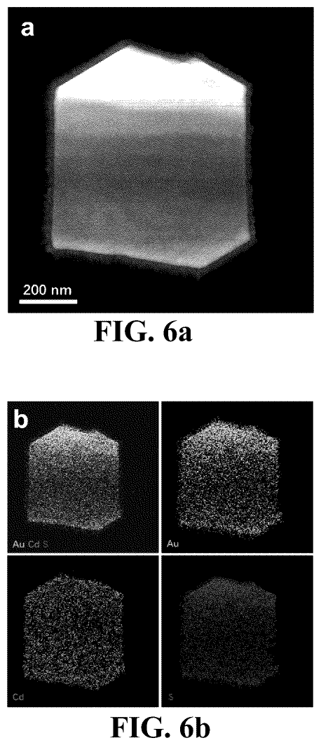

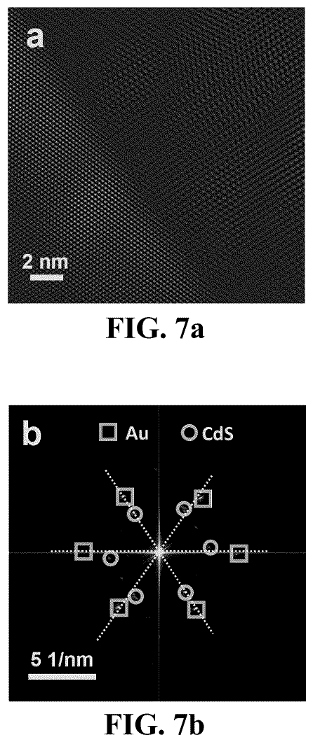

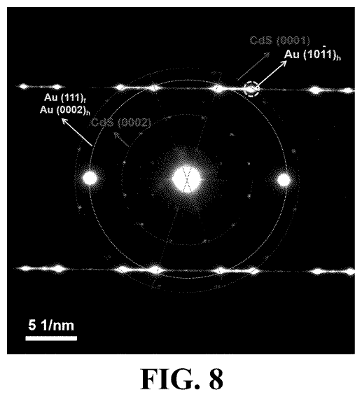

Referring to FIGS. 5a to 8, the formed 2H/fcc Au—CdS metal-semiconductor heterostructure by aforesaid synthesizing method is characterized by HRTEM, Cs-HAADF-STEM, XPS and SEM. FIG. 5a shows the SEM image of epitaxial 2H/fcc Au—CdS metal-semiconductor heterostructure, and demonstrates that the CdS nanorods vertically grow on 2H/fcc Au nanosheets. Referring to FIG. 5b, the thickness of epitaxial 2H/fcc Au—CdS noble metal-semiconductor heterostructure is determined to be about 30 nm. Referring to FIG. 6b. FIG. 6b demonstrates that Cd and S elements constructed homogeneous branches on the 2H/fcc Au nanosheets. Referring to FIG. 7a, FIG. 7a shows an abrupt interface between 2H/fcc Au nanosheets and CdS. Referring to FIG. 7b, FIG. 7b shows the aligned spots in the FFT pattern demonstrate that the CdS are epitaxially grown on 2H/fcc Au nanosheets. Referring to FIG. 8, the SAED pattern in FIG. 8 demonstrates the epitaxial relationship of 2H Au (110)∥CdS (101) and the epitaxial relationship of 2H Au (10-11)∥CdS (001).

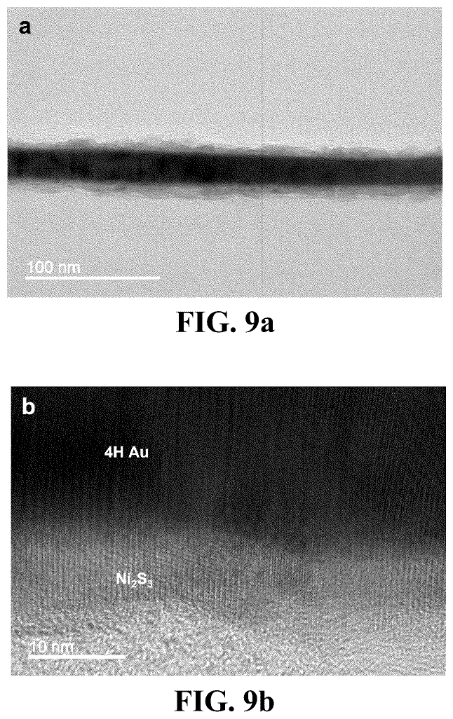

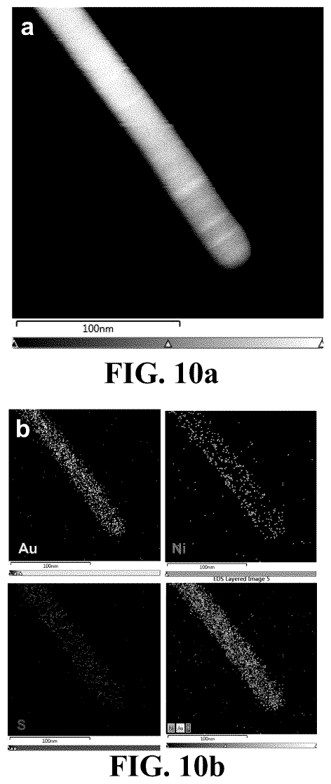

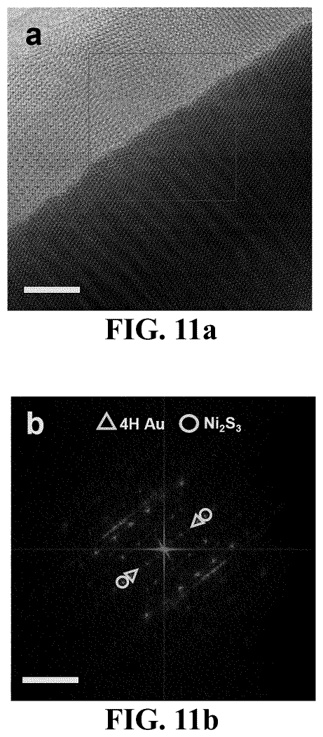

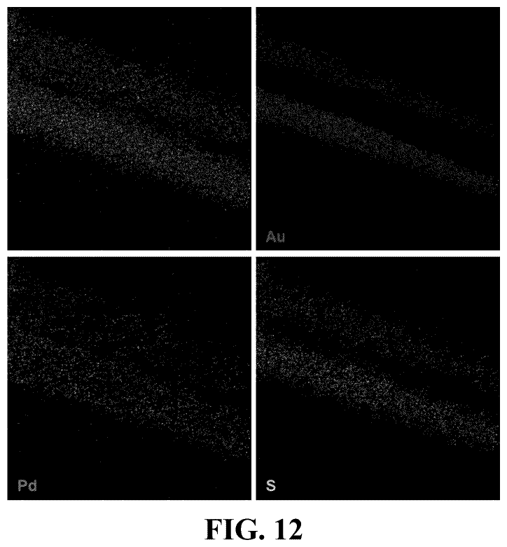

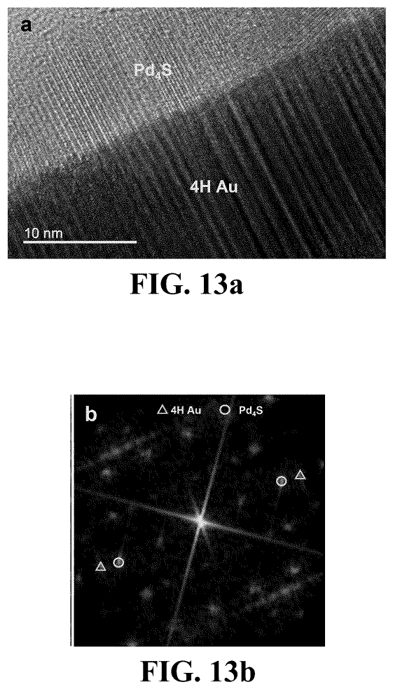

The semiconductor Pd₄S and Ni₂S₃ can be grown on 4H Au seeds with core shell structures. Taking Ni₂S₃ for an example, referring to FIGS. 9a to 10b, the Ni and S elements construct homogeneous shells on the 4H Au seeds (nanowires). Referring to FIG. 11a, FIG. 11a shows an abrupt interface between 4H Au and Ni₂S₃. Referring to FIG. 11b, the aligned spots in the FFT pattern demonstrate that the Ni₂S₃ shells are epitaxially grown on 4H Au seeds. Similarly, as shown in FIG. 12, the Pd and S elements construct homogeneous shells on the 4H Au nanowires. Referring to FIG. 13a, FIG. 13a shows the abrupt interface between 4H Au seeds and Ni₂S₃. On the other hand, referring to FIG. 13b, the aligned spots in the FFT pattern demonstrate that the Pd₄S shells are epitaxially grown on 4H Au seeds.

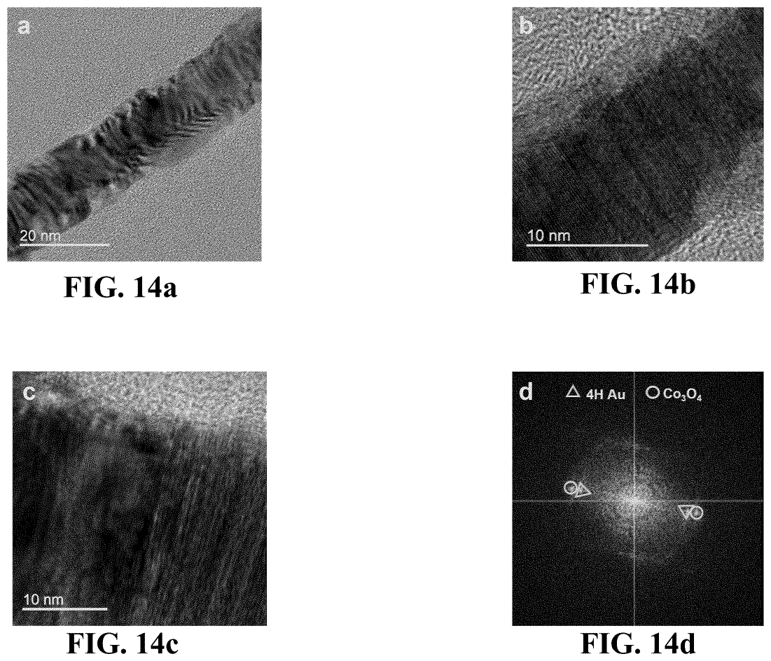

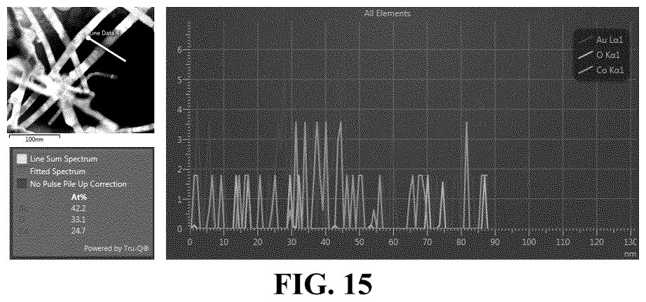

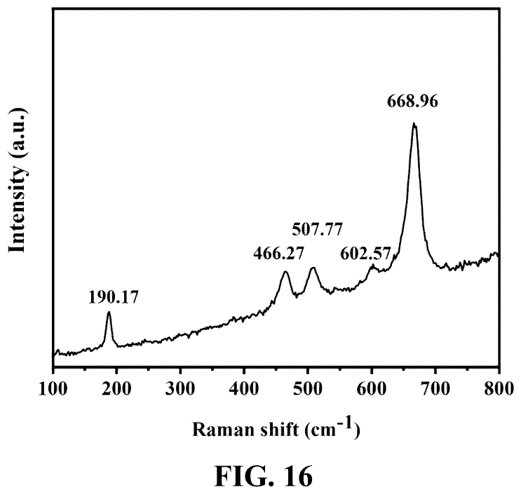

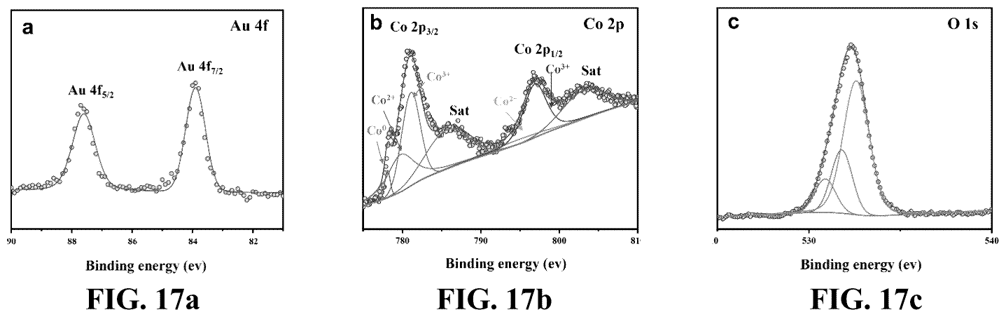

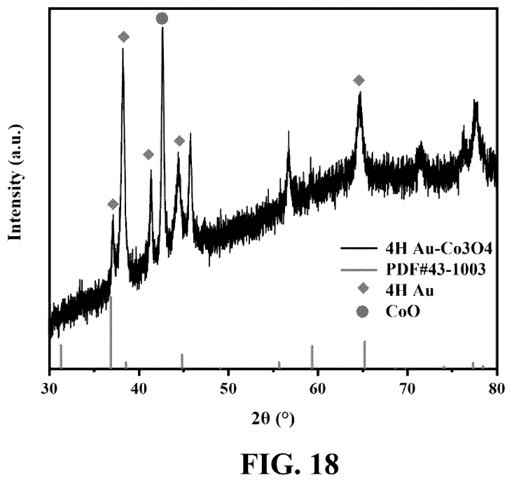

The metal oxide (e.g., Co₃O₄, Fe₃O₄, and NiO) can also epitaxially grow on Au with, for example, a 4H phase as aforesaid paragraphs. Taking Co₃O₄ for an example, referring to FIG. 14a, the Co₃O₄ can grow on 4H Au with core shell structures. Referring to FIGS. 14b and 14c, FIGS. 14b and 14c show an abrupt interface between 4H Au seed and Co₃O₄. Referring to FIG. 14d, the aligned spots in the FFT pattern demonstrate that the Co₃O₄ shells are epitaxially grown on 4H Au seeds. The Co and O elements construct homogeneous shells on the 4H Au nanowires as evidenced by the EDS line scan result as shown in FIG. 15. Referring to FIGS. 16 to 18, the Raman (FIG. 16), XPS (FIG. 17), and XRD (FIG. 18) spectra confirm that the existence of Co₃O₄ and the 4H phase of Au seeds can be maintained after the growth of Co₃O₄.

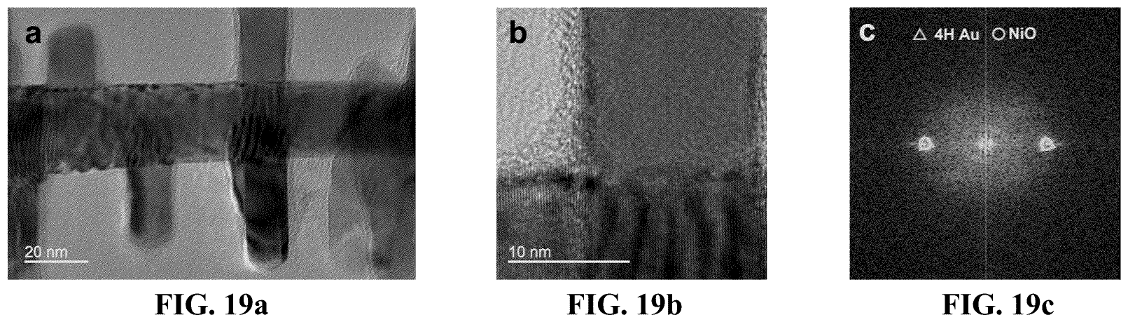

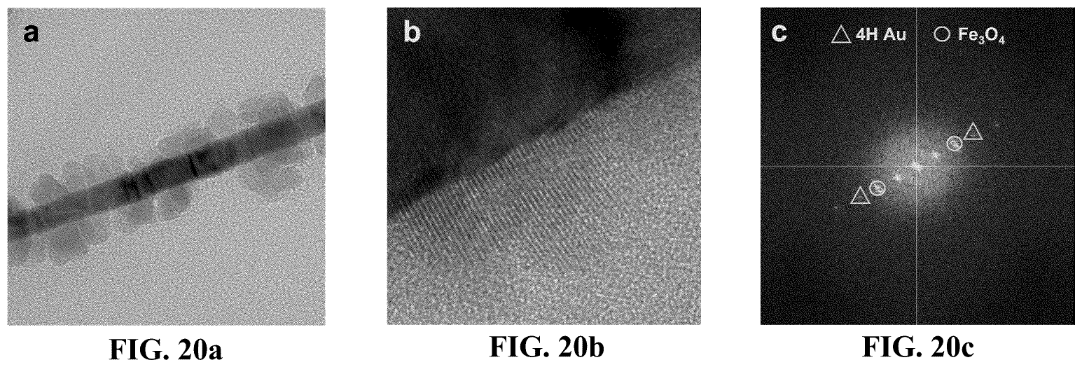

For the 4H Au—NiO metal-semiconductor heterostructure and 4H Au—Fe₃O₄ metal-semiconductor heterostructure, both of them are formed to have epitaxial 1D-1D structures. Referring to FIG. 19a, FIG. 19a shows that NiO can grow on 4H Au seeds. Referring to FIG. 19b, FIG. 19b shows that an abrupt interface between 4H Au seed and NiO. Referring to FIG. 19c, FIG. 19c shows that the aligned spots in the FFT pattern demonstrate that the NiO shells are epitaxially grown on 4H Au seeds. On the other hand, referring to FIG. 20a, FIG. 20a shows that Fe₃O₄ can grow on 4H Au seeds. Referring to FIG. 20b, FIG. 20b shows that an abrupt interface between 4H Au seed and Fe₃O₄. Referring to FIG. 20c, FIG. 20c shows that the aligned spots in the FFT pattern demonstrate that the Fe₃O₄ shells are epitaxially grown on 4H Au seeds.

Then, the quantum yield (QY) of the noble metal-semiconductor heterostructure synthesized by the present invention is measured, in which 4H Au—CdS noble metal-semiconductor heterostructure is taken as an example. In the embodiment of the present invention, the quantum efficiency measurement is, for example, measured by a mid-IR pump-probe transient absorption (TA) spectroscopy measurement. The detailed measurement principle is described as follows.

### QY Measurement of the Plasmon-Induced Hot-Electron Transfer in 4H Au—CdS Noble Metal-Semiconductor Heterostructures

The QY of the plasmon-induced hot-electrons transferred from the 4H Au to the CdS under 600 nm excitation can be quantified by the mid-IR intraband absorption at around 3340 cm⁻¹ of conduction band (CB) electrons in CdS. The CB electron in CdS produces a broad IR absorption which can be attributed to the transition from 12 to a higher level (such as III). To determine the plasmon-induced hot-electron transfer QY, the amplitude of IR signal per CB electron of CdS is quantified, denoted as S₀. Hence, S₀ can be calculated by Eq. 1:

$${S}_{0} = \frac{Δ A ( CdS , 400 nm )}{N ( CdS CB electrons )} \qquad ( 1 )$$

where ΔA is the maximum signal amplitude obtained from the kinetics, N (CdS CB electrons) is the number of electrons in CB band of CdS, which can be determined by the number of absorbed photons by CdS (every photon creates one electron in CB band of CdS under 400 nm excitation). Therefore, N (CdS CB electrons) equals the pump photon flux in the pump/probe overlap region times the sample absorption

$$( \frac{power / hv}{beam size} \times ( 1 - 1 {0}^{- OD} ) ) ,$$

where hv is photon energy.

The QY is calculated by the number of hot electrons generated in Au—CdS per absorbed photons under 550 nm excitation, as shown in Eq. 2.

$$QY = \frac{N ( hot electrons )}{N ( absorbed photons )} = \frac{\frac{Δ A ( Au - CdS , 600 nm )}{{S}_{0}}}{\frac{power ( 600 nm ) / hv ( 600 nm )}{beam size ( 600 nm )} \times ( 1 - {10}^{- OD ( Au - CdS , 600 nm )} )} = \frac{beam size ( 600 nm )}{beam size ( 400 nm )} \times [ \text{} \frac{\frac{Δ A ( Au - CdS , 600 nm )}{power ( 600 nm ) / hv ( 600 nm )}}{( 1 - {10}^{- OD ( Au - CdS , 600 nm )} )} / \frac{\frac{Δ A ( CdS , 400 nm )}{power ( 400 nm ) / hv ( 400 nm )}}{( 1 - {10}^{- OD ( CdS , 400 nm )} )} ] \qquad ( 2 )$$

In Eq. 2, beam size (600 nm) and beam size (400 nm) represent the overlap areas of pump and probe beams under 550 nm, and 400 nm pump laser excitation, respectively, whose ratio can be determined in a calibration sample (Cd₃P₂ quantum dots in this work) under the same conditions. The calibration sample is excited at both wavelengths and is expected to have the same QY for generating CB electrons. Then beam size (600 nm)/beam size (400 nm) can be described as follows:

$$\frac{beam size ( 600 nm )}{beam size ( 400 nm )} \times \text{} \frac{\frac{Δ A ( {Cd}_{3} {P}_{2} , 400 nm )}{power ( 400 nm ) / hv ( 400 nm )}}{( 1 - {10}^{- OD ( {Cd}_{3} {P}_{2} , 400 nm )} )} / \frac{\frac{Δ A ( {Cd}_{3} {P}_{2} , 600 nm )}{power ( 600 nm ) / hv ( 600 nm )}}{( 1 - {10}^{- OD ( {Cd}_{3} {P}_{2} , 600 nm )} )} \qquad ( 3 )$$

Thus, the QY of plasmon-induced hot-electron is given by Eq. 4.

$$QY = \frac{\frac{Δ A ( Au - CdS , 600 nm )}{1 - {10}^{- OD ( Au - CdS , 600 nm )}}}{\frac{Δ S ( CdS , 400 nm )}{1 - {10}^{- OD ( CdS , 400 nm )}}} \times \frac{\frac{Δ S ( {Cd}_{3} {P}_{2} , 400 nm )}{1 - {10}^{- OD ( {Cd}_{3} {P}_{2} , 400 nm )}}}{\frac{Δ S ( {Cd}_{3} {P}_{2} , 600 nm )}{1 - {10}^{- OD ( {Cd}_{3} {P}_{2} , 600 nm )}}} \qquad ( 4 )$$

Here, ΔS is defined as the following equation, which is

$$Δ S = \frac{Δ A}{power} .$$

ΔS represents that a quantity to be obtained from the transient IR measurement. To improve the measurement accuracy and to check the linearity of the signal, ΔA as a function of excitation power is measured for all samples. The TA signal amplitude increases linearly with the excitation power. ΔS can be obtained from the slope of the fitted linear line. For all samples, the optical density (OD) is controlled at around 0.2 to 0.8. It should be noted that because the CdS nanorods are directly grown on the 4H Au seeds, there may be slight differences in the diameter of the CdS nanorods control sample compared to the diameter of the nanorods in the heterostructure. This could affect the QY as the optical properties of the nanorods are dependent upon their size (absorption cross section); therefore, the QY for each sample is calculated using the independently synthesized CdS nanorods.

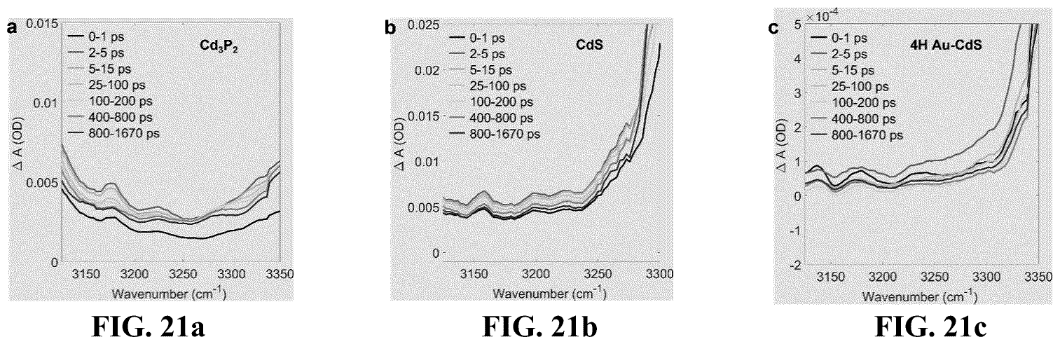

Referring to FIG. 21, the mid-IR pump-probe TA spectroscopy measurement reveals that the high quantum yield (˜2.64%) of plasmon-induced charge transfer from 4H Au to CdS in 4H Au—CdS 1D-1D heterostructures. This result breaks the stereotype that only small plasmonic noble metals (<10 nm) can achieve high QY. For instance, the QY would be less than 1% in Au-tipped CdS nanorods when the diameter of Au nanoparticle is larger than 6 nm. However, high QYs (about 2.64%) have been achieved in the 4H Au—CdS noble metal-semiconductor heterostructure of the present invention with large size Au (e.g., size of Au is about 1000 to 3000 nm), indicating the superiority and significance of epitaxial interfaces of the noble metal-semiconductor heterostructure of the present invention.

As known, the world is suffering from serve energy and environmental crisis due to the increasing concentration of CO₂ in the atmosphere due to the huge consumption of fossil fuels. Carbon neutrality has become the target of the whole human society. Harvesting the abundant, clean, and free solar energy to convert CO₂ into fuel chemicals has been regarded as an ideal strategy to utilize CO₂ and simultaneously store solar energy in chemicals, which is also named as artificial photosynthesis. However, artificial photosynthesis faces several problems. First, CO₂ has a low solubility in water and the presence of excess H⁺ in water promotes the competing H₂ evolution, which is thermodynamically and kinetically more favorable than CO₂ reduction. Second, the conventional photocatalyst used in the artificial photosynthesis suffers from low quantum efficiency due to the photo-induced holes being hard to consume, commonly sacrificial agent is needed, which greatly restricts the real application of artificial photosynthesis. Third, since the photo-induced holes induced in artificial photosynthesis can oxide the conventional photocatalyst and cause self-corrosion, the conventional photocatalyst suffers from low stability.

As photo-induced electrons and holes are efficiently separated in epitaxial 4H Au—CdS 1D-1D heterostructures of the present invention, together with the superior CO₂ reduction performance of 4H Au, the epitaxial 4H Au—CdS 1D-1D heterostructures of the present invention can be used as a highly efficient photocatalyst for photocatalytic CO₂ reduction to address the aforesaid issues. In the present invention, the other aforesaid formed noble metal-semiconductor heterostructures (e.g., 4H Au—NiS. 4H Au—Pd₄S, 4H Au—Fe₃O₄, 4H Au—NiO, 4H Au—CoO, 4H/fcc Au—CdS, or 2H/fcc Au—CdS) also exhibit excellent separation ability of photo-induced electrons and holes, and thus they can also serve as a photocatalyst for photocatalytic CO₂ reduction. In the embodiments of the present invention, a photocatalytic system including the noble metal-semiconductor heterostructures, synthesized by aforesaid methods, for the photocatalytic reduction of carbon dioxide (CO₂) is also provided. The detailed structure of the photocatalytic system including 4H Au—CdS noble metal-semiconductor heterostructure and its effects will be described as an example in the following paragraphs.

In detail, the photocatalytic system includes a container, a strong alkaline substance, a photocatalyst, and a photo-hole sacrificial reagent. The container includes water. The strong alkaline substance is dissolved in the water of the container, such that a strong alkali solution is formed in the container. The photocatalyst includes the aforesaid noble metal-semiconductor heterostructure, and is dissolved in water of the container. The photo-hole sacrificial reagent is disposed in the water of the container.

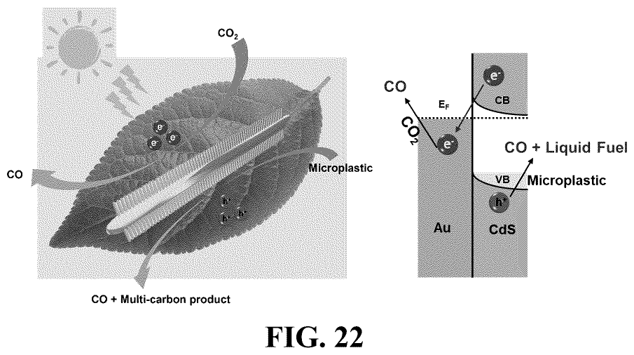

To be more specific, the strong alkaline substance can be, for example, potassium hydroxide (KOH), and the strong alkali solution can be KOH aqueous solution (i.e., 10 M KOH aqueous solution), which greatly increases the solubility of CO₂ in water. A material of the photo-hole sacrificial reagent can be, for example, microplastic. A material of the microplastic can be, for example, polyethene (PE), polyvinyl chloride (PVC), or polyethylene terephthalate (PET). The function of the photo-hole sacrificial reagent is to reduce the negative effect of photo-induced hole on the photocatalyst, so as to improve quantum efficiency of photocatalytic CO₂ reduction reactions as shown in FIG. 22. The detailed preparing process of the photocatalytic system of the present invention will be fully described as follows.

10 mg 4H Au—CdS noble metal-semiconductor heterostructures of the present invention are dissolved in 5 mL chloroform and 1 mL N, N-Dimethylformamide. Then, 1 ml of 1.0 M triethyloxonium tetrafluoroborate in methylene chloride is added into the 4H Au—CdS noble metal-semiconductor heterostructures under Argon. Next, the formed solution is stirred for 1 h, and the 4H Au—CdS noble metal-semiconductor heterostructures are collected by centrifugation at 4000 to 10000 rpm for 1 to 5 min. The product is washed by acetonitrile for 3 times and dried under vacuum. Finally, the dried Au—CdS noble metal-semiconductor heterostructures are dispersed in 10 mL of 10M KOH solution.

Next, 10 mg of Au—CdS noble metal-semiconductor heterostructures in 10 mL of 10M KOH solution are mixed with 100 mg of microplastic (e.g., PE) and are pumped with CO₂ to saturation. The above-mentioned solution is put into a quartz photocatalytic reactor filled with 80 kPa of CO₂, and the reactor is irradiated with a 300 W Xe lamp (e.g., Microsolar 300, Perfect Light) equipped with a solar simulator filter with slight stirring. The light intensity is measured with a power meter (PM100D, THORLABS). The evolved gas produced is sampled periodically by a gas chromatography (Agilent, 8890) equipped with a thermal conductive detector (TCD) and flame ionization detector (FID) using argon as the carrier gas. The solution products are identified by gas chromatography spectrometry (GC, Agilent 7890A-5975C with a DB-Waxetr column).

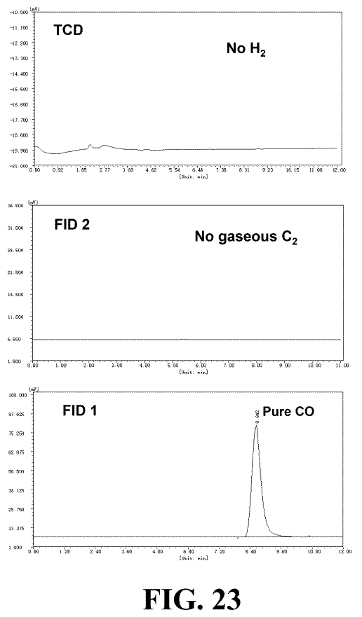

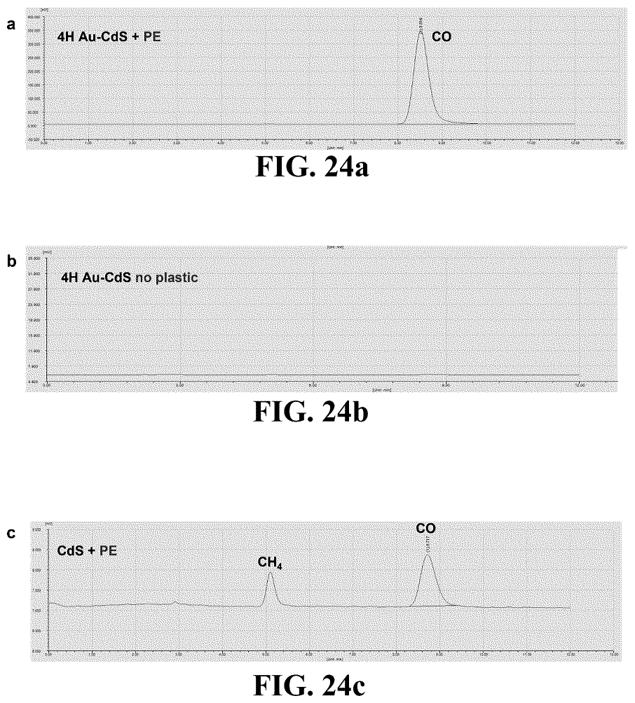

Referring to FIG. 23, as shown in the GC spectra, in the photocatalytic CO₂ reduction reactions of a case 1 using the 4H Au—CdS noble metal-semiconductor heterostructure mixed with PE plastic, the gas product is pure CO indicating the competing H₂ evolution is greatly suppressed. The gas product is almost pure CO without any H₂. This solves the problem that the presence of excess H⁺ in water promotes the competing H₂ evolution, which is thermodynamically and kinetically more favorable than CO₂ reduction. It is found that the addition of photo-hole sacrificial reagent (e.g., microplastic) can efficiently consume photo-induced holes and greatly increase the quantum efficiency of photocatalytic CO₂ reduction reactions. For instance, compared with a case 2 of using blank epitaxial 4H Au—CdS noble metal-semiconductor heterostructure instead of microplastics, the CO evolution rate of case 1 increases by more than that of case 2 1000 times (as shown in FIGS. 24a and 24b).

Compared with a case 3 of using blank CdS nanorods, the case 1 shows much higher selectivity in the photocatalytic CO₂ reduction reactions. In detail, the gas product of case 1 is 100% CO, but the gas product of case 3 is about 65% CO, 25% CH₄ and 10% H₂ (as shown in FIG. 24c).

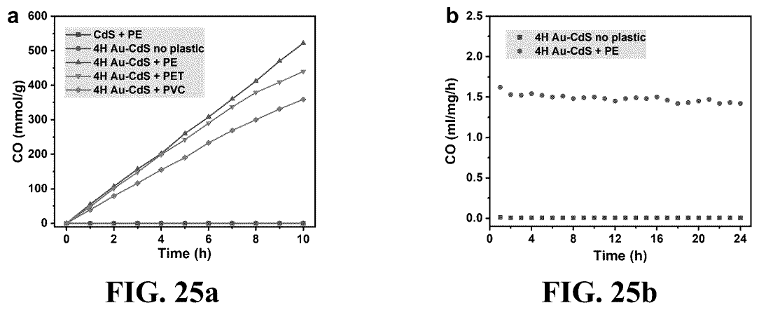

In other embodiments, the microplastic can be PVC or PET. Referring to FIGS. 25a and 25b, in cases of using PVC microplastic and PET microplastic can also increase the quantum efficiency of photocatalytic CO₂ reduction reactions. Referring to FIG. 25b, during the photocatalytic CO₂ reduction reaction using the photocatalytic system of the present invention, the epitaxial 4H Au—CdS noble metal-semiconductor heterostructure is very stable and can produce CO at the rate of 1.5 L/g/hour for more than 24 hours without any decrease, solving the self-corrosion of the photocatalyst.

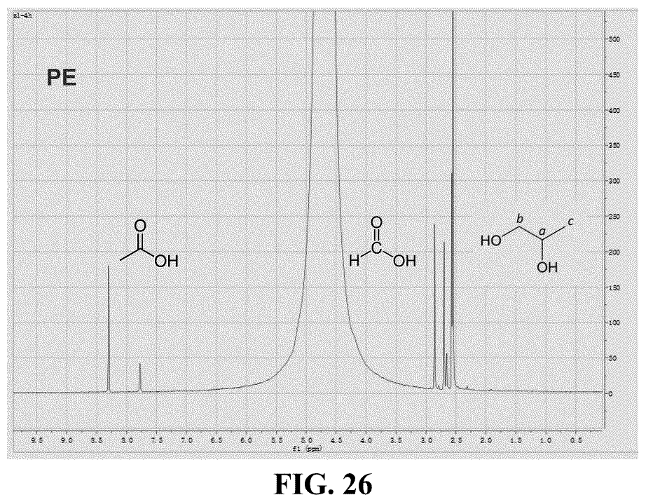

Meanwhile, the microplastics for photo-hole sacrificial reagent would be degraded into liquid fuel (i.e., formic acid and acetic acid) during the photocatalytic CO₂ reduction reaction, which means that the synthesized noble metal-semiconductor heterostructure of the present invention can solve the problem of increasing CO₂ in the atmosphere and microplastic. As shown in FIG. 26, the NMR spectra of liquid products in the synchronously photocatalytic CO₂ reduction and PE microplastic reforming reactions using epitaxial 4H Au—CdS noble metal-semiconductor heterostructure, the signal of formic acid, acetic acid and isopropanol can be found (FIG. 25), indicating the carbon-carbon long-chain has been degraded.

Referring to FIG. 26, the SEM images of the PE microplastics before and after photocatalysis demonstrate the PE microplastics are severely corroded after the reaction. The unique 1D-1D multi-branched structure of epitaxial 4H Au—CdS 1D-1D heterostructures enables the 4H Au—CdS firmly attached to PE microplastics, which greatly increase the photocatalytic efficiency.

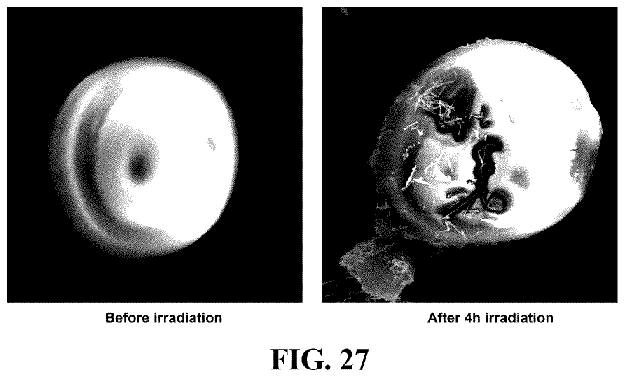

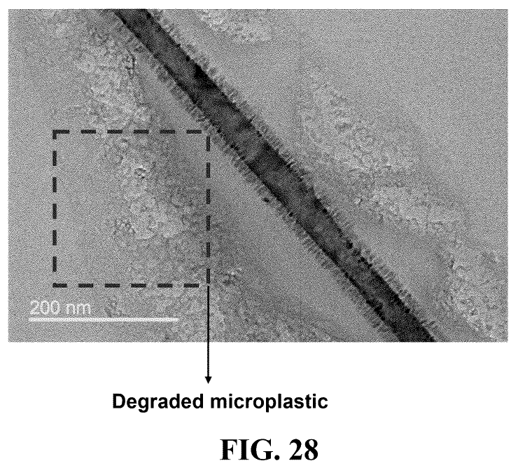

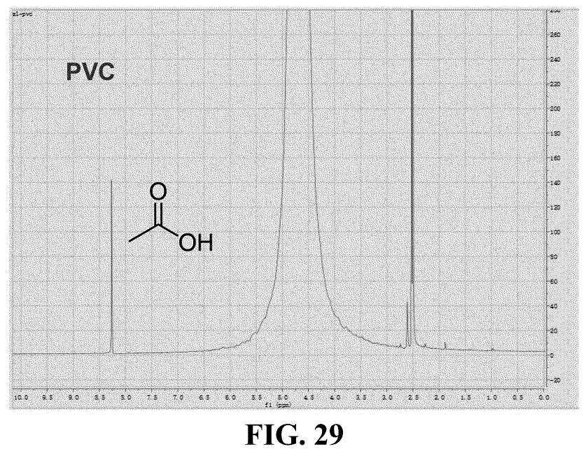

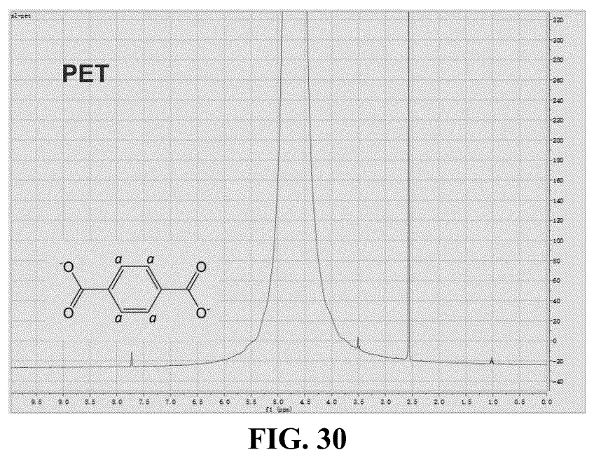

Referring to FIG. 27, the HRTEM image of epitaxial 4H Au—CdS noble metal-semiconductor heterostructure after photocatalysis shows the 1D-1D multi-branched structure of 4H Au—CdS is maintained, demonstrating the high stability of the 4H Au—CdS photocatalyst. Similarly, referring to FIGS. 28 and 29, in the NMR spectra of liquid products in the photocatalytic CO₂ reduction using PVC (see FIG. 28) and PET (see FIG. 29), the signal of short-chain organics indicating the microplastics have been degraded into liquid fuel.

In the embodiments of the present disclosure, a robust and novel wet-chemical method for synthesizing noble metal-semiconductor heterostructures is provided. By performing the aforesaid steps of the synthesizing method, epitaxial growth of a library of semiconductor nanomaterials on Au nanomaterials with a 4H phase, a 4H/fcc phase, and a 2H/fcc heterophase can be achieved. The formed noble metal-semiconductor heterostructures of the present invention have excellent stability and QY, and they are very suitable as photocatalysts for the reduction reactions of CO₂.

For example, in some cases, the formed 4H Au—CdS noble metal-semiconductor heterostructures can be used in a photocatalytic system of the present invention for photocatalytic reduction of CO₂. The strong alkali aqueous solution is applied in the photocatalytic system, which greatly increase the solubility of CO₂. Further, due to the superior CO₂ reduction performance of 4H Au of the 4H Au—CdS noble metal-semiconductor heterostructures, the competing H₂ evolution is greatly suppressed. The gas product of the photocatalytic reaction is almost pure CO without any H₂. Moreover, it is found that the addition of photo-hole sacrificial reagent (e.g., microplastic) can efficiently consume photo-induced holes and greatly increase the quantum efficiency of photocatalytic CO₂ reduction reactions. For instance, after adding poly ethylene (PE) microplastics, the CO evolution rate increases by more than 1000 times. Meanwhile, it is found that the microplastics would be degraded into liquid fuel (i.e., formic acid and acetic acid), which means that noble metal-semiconductor heterostructures of the present invention can synchronously solve the problem of increasing CO₂ in the atmosphere and microplastic. In some cases, noble metal-semiconductor heterostructures of the present invention are very stable and can produce CO at the rate of 1.5 L/g/hour for more than 24 hours without any decrease. That is to say, the invention can simultaneously perform photocatalytic conversion of CO₂ and convert microplastic into fuel (for example, CO).

It should be noted that in the above example, the noble metal-semiconductor heterostructure is applied in the photocatalytic system. In other embodiments, the noble metal-semiconductor heterostructure can also be used in other devices of other fields.

The embodiments were chosen and described in order to best explain the principles of the invention and its practical application, thereby enabling others skilled in the art to understand the invention for various embodiments and with various modifications that are suited to the particular use contemplated.

As used herein and not otherwise defined, the terms “substantially.” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

What is claimed is:

1. A method for synthesizing noble metal-semiconductor heterostructures, comprising:
Step S1: forming noble metal seeds;
Step S2: mixing at least one metal precursors comprising a first metal and a first solvent in a first reactor chamber, so as to obtain a first solution comprising a first mixture;
Step S3: heating the first solution with a first heating process, so as to obtain a transparent solution;
Step S4: mixing the noble metal seeds, the transparent solution, and a second solvent, so as to obtain a second solution; and
Step S5: heating the second solution with a second heating process to grow a semiconductor structure containing the first metal on the noble metal seeds, thereby forming the noble metal-semiconductor heterostructures therein.

2. The method of claim 1, wherein the step S1 further comprises:
Step S11: mixing a noble metal salt and a third solvent in a reaction chamber, so as to obtain a third solution;
Step S12: heating the reaction chamber containing the third solution with a third heating process, such that the noble metal seeds are formed in the third solution; and
Step S13: collecting the noble metal seeds from the reaction chamber after the third heating process.

3. The method of claim 2, wherein,
in the step S11, the noble metal salt comprises an noble metal;
in the step S12, the third heating process comprises a sub-step of performing an oil bath on the sealed reaction chamber with the third solvent at a constant temperature for a given time period; and
in the step S13, a centrifugation procedure is performed on the reaction chamber with the third solution, and then the reaction chamber is washed for a plurality of times through toluene, so that the noble metal seeds are dispersed therein.

4. The method of claim 3, wherein
in the step S12, the third solvent is selected from one of the following two combinations 1, 2:
combination 1: oleylamine, N-ethylcyclohexylamine, hexane and 1,2-dichloropropane; and
combination 2: 4-tert-butylpyridine, oleylamine and heptane.

5. The method of claim 3, wherein the noble metal salt comprises HAuCl₄·3H₂O.

6. The method of claim 1, wherein the noble metal seeds have a 4H phase, a 4H/fcc phase, or a 2H/fcc phase.

7. The method of claim 1, wherein the metal precursors comprise at least one of metal oxide comprising the first metal and metal halide comprising the first metal.

8. The method of claim 7, wherein the metal halide comprises chlorine (Cl).

9. The method of claim 1, wherein the first metal comprises cadmium (Cd), nickel (Ni), iron (Fe), cobalt (Co), or platinum (Pt).

10. The method of claim 1, wherein the metal precursor comprises metal oleate comprising the first metal.

11. The method of claim 10, wherein the first metal comprises iron (Fe), nickel (Ni), or cobalt (Co).

12. The method of claim 1, wherein a mixing process of the step S4 further mixes with an inorganic salt having the same element as the semiconductor structure.

13. The method of claim 12, wherein the inorganic salt comprises NH₄SCN, and the same element of the inorganic salt and the semiconductor structure is sulfur(S).

14. The method of claim 1, wherein the second solvent comprises oleylamine.

15. The method of claim 1, wherein the second heating process comprises a sub-step of heating the second solution within a temperature range for a given time period.

16. The method of claim 1, wherein the second heating process comprises a sub-step of heating the second solution with a constant temperature increasing rate for a given time period.

17. The method of claim 1, further comprises a step S6: collecting the noble metal-semiconductor heterostructure.

18. A photocatalytic system for the photocatalytic reduction of carbon dioxide (CO₂), comprising:
a container, containing water;
a strong alkaline substance, dissolved in water of the container;
a photocatalyst comprising noble metal-semiconductor heterostructures, wherein the noble metal-semiconductor heterostructures comprise noble metal seeds and a semiconductor structure formed thereon, wherein the photocatalyst is dissolved in water of the container; and
a photo-hole sacrificial reagent disposed in the water of the container.

19. The photocatalytic system of claim 18, wherein,
the strong alkaline substance comprises potassium hydroxide (KOH);
the noble metal-semiconductor heterostructures comprise 4H Au—CdS, 4H Au—NiS, 4H Au—Pd₄S, 4H Au—Fe₃O₄, 4H Au—NiO, 4H Au—CoO, 4H/fcc Au—CdS, or 2H/fcc Au—CdS; and
the photo-hole sacrificial reagent comprises polyethene (PE), polyvinyl chloride (PVC), or polyethylene terephthalate (PET).

20. The photocatalytic system of claim 18, wherein the noble metal-semiconductor heterostructures is an 1D-1D heterostructure or a 2D-1D heterostructure.
